(19) United States
(12) Patent Application Publication
(10) Pub. No.: US 2022/0114835 A1
(43) Pub. Date: Apr. 14, 2022

(54) LIGHT-EMITTING DEVICE, OPTICAL DEVICE, AND INFORMATION PROCESSING DEVICE

(71) Applicant: FUJIFILM BUSINESS INNOVATION CORP., Tokyo (JP)

(72) Inventors: Takeshi MINAMIRU, Ebina-shi (JP); Satoshi INADA, Ebina-shi (JP); Takafumi HIGUCHI, Ebina-shi (JP); Shigetoshi NAKAMURA, Ebina-shi (JP); Kenichi ONO, Ebina-shi (JP)

(73) Assignee: FUJIFILM BUSINESS INNOVATION CORP., Tokyo (JP)

(21) Appl. No.: 17/559,626

(22) Filed: Dec. 22, 2021

Related U.S. Application Data
(63) Continuation of application No. PCT/JP2019/048789, filed on Dec. 12, 2019.

(30) Foreign Application Priority Data
Aug. 8, 2019 (JP) 2019-146382

(51) Int. Cl. G06V 40/16; H04N 13/307; G06V 10/147; G06V 10/141; G06V 10/422

(52) U.S. Cl. CPC G06V 40/166; H04N 13/307; G06V 10/422; G06V 10/141; G06V 10/147

(57) ABSTRACT

A light-emitting device includes: a light source including plural light-emitting elements; a first optical member that is provided in a light-emitting path of the light source, the first optical member being configured to narrow a spread angle of light emitted from each of the light-emitting elements of the light source and emit the narrowed light; and a second optical member that is provided on a light-emitting side of the first optical member and is configured to diffuse and irradiate light incident from the first optical member.

### CROSS-REFERENCE TO RELATED APPLICATIONS

This is a continuation of International Application No. PCT/JP2019/048789 filed on Dec. 12, 2019, and claims priority from Japanese Patent Application No. 2019-146382 filed on Aug. 8, 2019.

### BACKGROUND

### Technical Field

The present invention relates to a light-emitting device, an optical device, and an information processing device.

### Related Art

Patent Literature 1 describes an imaging device including a light source, a diffusion plate that includes plural lenses arranged adjacent to each other on a predetermined plane and diffuses light emitted from the light source, and an imaging element that receives light that is diffused by the diffusion plate and reflected on a subject, in which the plural lenses are arranged in such a manner that a pitch of interference fringes in the diffused light is three pixels or less.

### CITATION LIST

### Patent Literature

Patent Literature 1: JP-A-2018-54769

### SUMMARY

When a three-dimensional shape is measured by a time-of-flight method, in order to emit light to a measurement target, it is required to diffuse light emitted from a light source and irradiate a predetermined range with a predetermined light intensity distribution. At this time, the light reaches the outside of the predetermined range while gradually attenuating the intensity, but the light reaching the outside of the predetermined range is wasted.

Aspects of non-limiting embodiments of the present disclosure relate to providing a light-emitting device and the like in which an amount of light reaching outside a predetermined range is reduced compared to a case where a spread angle of light emitted from a light-emitting element of a light source is not narrowed.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light-emitting device including: a light source including plural light-emitting elements; a first optical member that is provided in a light-emitting path of the light source, the first optical member being configured to narrow a spread angle of light emitted from each of the light-emitting elements of the light source and emit the narrowed light; and a second optical member that is provided on a light-emitting side of the first optical member and is configured to diffuse and irradiate light incident from the first optical member side.

### BRIEF DESCRIPTION OF DRAWINGS

Exemplary embodiment(s) of the present invention will be described in detail based on the following figures, wherein:

FIG. 1 illustrates an example of an information processing device to which a first exemplary embodiment is applied;

FIG. 2 illustrates three-dimensional shape measurement performed by the information processing device;

FIG. 3A illustrates an example of an irradiation pattern on an irradiated surface;

FIG. 3B illustrates a light intensity distribution along line A-A of FIG. 3A;

FIG. 4 is a block diagram illustrating a configuration of the information processing device;

FIG. 5A illustrates an example of a plan view of an optical device to which the first exemplary embodiment is applied;

FIG. 5B is a cross-sectional view of the optical device taken along line VB-VB of FIG. 5A;

FIG. 6 illustrates an example of a plan view of a light source;

FIG. 7 illustrates a cross-sectional structure of a multi-mode VCSEL having a single λ resonator structure included in the light source;

FIG. 8 schematically illustrates a spread angle a of light emitted from the multi-mode VCSEL;

FIG. 9 illustrates a relationship between a spread angle of light emitted from a VCSEL-A, a skirt spread amount, and light use efficiency on an irradiated surface;

FIG. 10 schematically illustrates a relationship among a light source in a light-emitting device to which the first exemplary embodiment is applied, a convex lens as an example of a spread angle narrowing member 20, and a diffusion plate;

FIG. 11 schematically illustrates a relationship among the light source in the light-emitting device to which the first exemplary embodiment is applied, a fly-eye lens as another example of a spread angle narrowing member, and the diffusion plate;

FIG. 12A illustrate an example of a plan view of an optical device to which a second exemplary embodiment is applied;

FIG. 12B is a cross-sectional view of the optical device taken along line XIIB-XIIB of FIG. 12A;

FIG. 13 schematically illustrates a relationship among a light source in a light-emitting device to which the second exemplary embodiment is applied, an array of microlenses as an example of a spread angle narrowing member, and a diffusion plate;

FIG. 14 illustrates a cross-sectional structure of a single-mode VCSEL having a single long resonator structure that forms the light source; and

FIG. 15 schematically illustrates a relationship among the light source in the light-emitting device to which the second exemplary embodiment is applied, a microlens as an example of the spread angle narrowing member, and the diffusion plate.

### DETAILED DESCRIPTION

Hereinafter, an exemplary embodiment of the present disclosure will be described in detail with reference to the accompanying drawings.

In many cases, an information processing device identifies whether a user who has accessed the information processing device is permitted to access the information processing device, and permits use of the information processing device, namely the own device, only when it is authenticated that the user is a user whose access is permitted. So far, methods of authenticating the user have used a password, a fingerprint, an iris, or the like. Recently, there is a demand for an authentication method having improved security. As this method, authentication is performed based on a three-dimensional image of a face of the user.

Here, an example in which the information processing device is a portable information processing terminal will be described, and the information processing device authenticates a user by recognizing a face that is captured as a three-dimensional image. The information processing device may be applied to an information processing device such as a personal computer (PC), other than the portable information processing terminal.

A configuration, function, method, or the like described in the present exemplary embodiment may be applied to acquisition of a three-dimensional image of an object in addition to the recognition of the face shape. That is, the present disclosure may also be applied to acquisition of a three-dimensional image in order to measure a three-dimensional shape of a measurement target that is an object other than the face. In addition, a distance to the measurement target (hereinafter, referred to as a measurement distance) does not matter. In the present exemplary embodiment, the face or the object other than the face that is a target of three-dimensional image acquisition may be referred to as an object to be irradiated or an object to be measured.

### First Exemplary Embodiment

### Information Processing Device 1

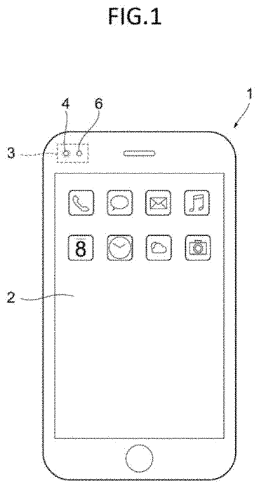

FIG. 1 illustrates an example of an information processing device 1 to which a first exemplary embodiment is applied. As described above, the information processing device 1 is, for example, a portable information processing terminal.

The information processing device 1 includes a user interface unit (hereinafter, referred to as a UI unit) 2 and an optical device 3 that acquires a three-dimensional image. The UI unit 2 is formed by integrating, for example, a display device that displays information to a user and an input device to which an instruction for information processing is input by an operation of the user. The display device is, for example, a liquid crystal display or an organic EL display. The input device is, for example, a touch panel.

The optical device 3 includes a light-emitting device 4 and a three-dimensional sensor (hereinafter, referred to as a 3D sensor) 6. The light-emitting device 4 emits light toward a measurement target whose three-dimensional shape is to be measured in order to acquire a three-dimensional image, that is, a face in the example described here. The 3D sensor 6 acquires light emitted by the light-emitting device 4, reflected by a face, and returned. The optical device 3 acquires the three-dimensional image of the face based on a so-called time-of-flight (TOF) method based on a flight time of light. In the following description, when the measurement target is the face, the face may be referred to as the measurement target.

The information processing device 1 is configured as a computer including a CPU, a ROM, a RAM, and the like. The ROM includes a non-volatile rewritable memory such as a flash memory. Programs and constants stored in the ROM are loaded onto the RAM. When the CPU executes the programs loaded onto the RAM, the information processing device 1 is operated to execute various types of information processing.

### Three-Dimensional Shape Measurement Performed by Information Processing Device 1

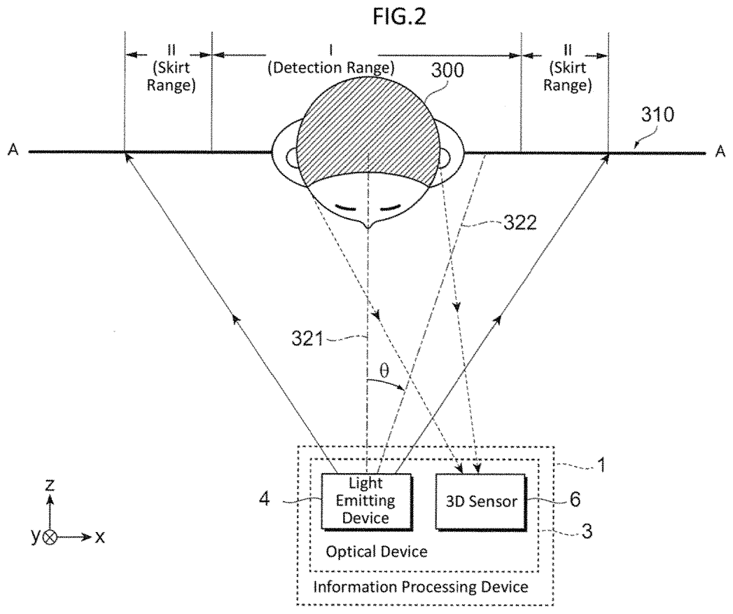

FIG. 2 illustrates three-dimensional shape measurement performed by the information processing device 1. A measurement target here is a face 300. As illustrated in FIG. 2, a right direction in FIG. 2 is defined as an x direction, an upper direction in FIG. 2 is defined as a z direction, and a back side direction perpendicular to a plane of FIG. 2 is defined as a y direction. FIG. 2 is a diagram in which a head including a face is viewed from above the head.

In the optical device 3 of the information processing device 1, light is emitted from the light-emitting device 4 toward the face 300. Then, the 3D sensor 6 receives the light reflected by the face 300. That is, the optical device 3 is configured such that light is emitted from the light-emitting device 4 toward the measurement target and the reflected light from the measurement target is received by the 3D sensor 6. At this time, the light-emitting device 4 emits light toward an irradiated surface 310 that is a virtual surface provided to face the light-emitting device 4. Here, the light-emitting device 4 and the irradiated surface 310 face each other. The light-emitting device 4 is located on a perpendicular line 321 to the irradiated surface 310. The perpendicular line 321 is drawn to a center of a detection range I to be described later. Line A-A passes through the center of the detection range I (intersection with the perpendicular line 321) and traverses on the irradiated surface 310 in the x direction. A line connecting the light-emitting device 4 and an arbitrary point on line A-A is defined as a line 322. An angle θ is an angle between the perpendicular line 321 and the line 322.

The detection range I, in which the face 300 is detected and a three-dimensional shape of the face 300 is measured, and a skirt range II surrounding the detection range I are formed on the irradiated surface 310. The detection range I is a range irradiated with light having light intensity that enables the three-dimensional shape of the face 300 to be measured by reflected light when the face 300 is present in this region. Meanwhile, the skirt range II is a range in which light intensity decreases as a distance from the detection range I increases. Therefore, even when the face 300 is present in the skirt range II, the three-dimensional shape of the face 300 is not measured with high accuracy as compared with the case where the face 300 is present in the detection range I. That is, the skirt range II is a non-detection range that is not suitable for measuring the three-dimensional shape of the face 300. The detection range I and the skirt range II are ranges where the light from the light-emitting device 4 is irradiated. The detection range I is a predetermined range for measuring the three-dimensional shape, and is a range irradiated with light with a predetermined light intensity distribution. Here, the light intensity refers to luminous intensity.

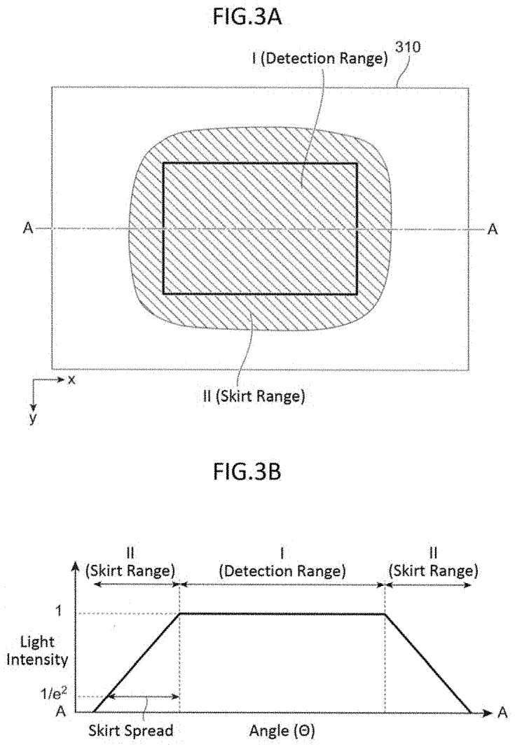

FIGS. 3A and 3B illustrate the irradiated surface 310. FIG. 3A illustrates an example of an irradiation pattern on the irradiated surface 310, and FIG. 3B illustrates a light intensity distribution along line A-A of FIG. 3A. A shape irradiated with the light on the irradiated surface 310, that is, a shape of a portion where the light is irradiated, is referred to as the irradiation pattern. In FIG. 3B, a horizontal axis represents the angle θ between the perpendicular line 321 and the line 322 illustrated in FIG. 2, and a vertical axis represents light intensity on the irradiated surface 310.

It is assumed that the irradiation pattern illustrated in FIG. 3A has a quadrangular shape whose longitudinal direction is oriented in the x direction and whose corners are rounded. In this irradiation pattern, a rectangular range surrounded by a solid line in a central portion is set as the detection range I, and a peripheral portion of the detection range I is set as the skirt range II. The skirt range II is formed outside the detection range I so as to surround the detection range I. The detection range I may be set to have a shape other than the rectangular shape.

The detection range I is set to have a predetermined light intensity distribution. Although it is assumed that light intensity of the detection range I is constant in FIG. 3B, the distribution may also vary within a predetermined allowable range. That is, as long as the light intensity enables measurement of a three-dimensional shape of the object to be irradiated, the distribution may vary in the region of the detection range I. For example, in the detection range I, light intensity of a center side may be weaker than light intensity of a peripheral side, or the light intensity of the center side may be stronger than the light intensity of the peripheral side. Meanwhile, in the skirt range II, the light intensity gradually decreases from the light intensity of the detection range I as the distance from the detection range I increases. Here, an angle difference from an angle of a boundary between the detection range I and the skirt range II to an angle at which the light intensity becomes l/e² of a maximum value in the skirt range II is defined as a skirt spread amount. The skirt spread amount indicates a size of the skirt range II. As described above, the skirt range II is unsuitable for measuring the three-dimensional shape of the face 300, and may be located out of the detection range used for measuring the three-dimensional shape. In this case, the light irradiated to the skirt range II is irradiated is ineffective. Therefore, use efficiency of the light emitted from the light-emitting device 4 (hereinafter, referred to as light use efficiency) is increased as an area of the skirt range II becomes smaller, that is, as the skirt spread amount becomes smaller. The light use efficiency refers to a ratio of an amount of light emitted into the detection range Ito an amount of light emitted by the light-emitting device 4. Then, the light with which the skirt range II is irradiated may be referred to as skirt light. The skirt spread amount may be evaluated by full width at half maximum (FWHM) of the light intensity. In addition, the skirt spread amount may be evaluated by an index other than the angle, for example, a width of the skirt range II on the irradiated surface 310 that is placed at a predetermined distance from the light-emitting device 4.

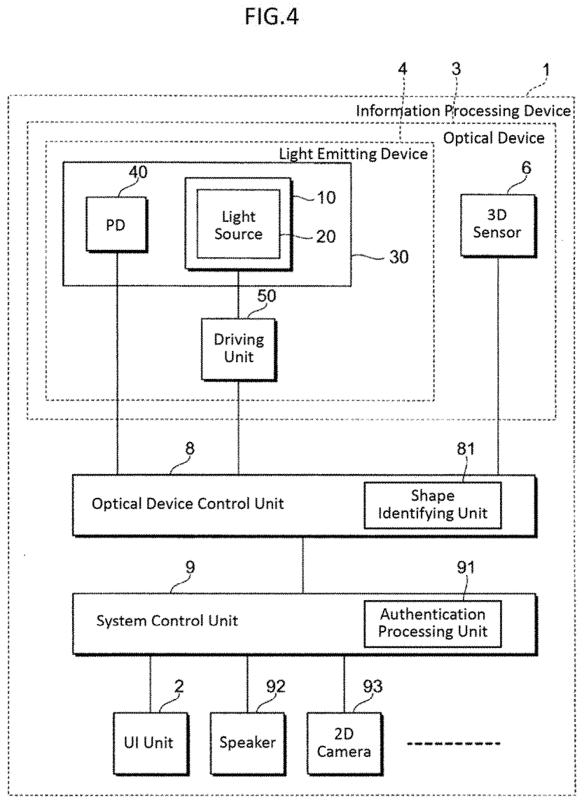

FIG. 4 is a block diagram illustrating a configuration of the information processing device 1.

The information processing device 1 includes the optical device 3 described above, an optical device control unit 8, and a system control unit 9. As described above, the optical device 3 includes the light-emitting device 4 and the 3D sensor 6. The optical device control unit 8 controls the optical device 3. The optical device control unit 8 includes a shape identifying unit 81. The system control unit 9 controls the entire information processing device 1 as a system. The system control unit 9 includes an authentication processing unit 91. Then, the UI unit 2, a speaker 92, and a two-dimensional camera (denoted as a 2D camera in FIG. 2) 93, and the like are connected to the system control unit 9. The 3D sensor 6 is an example of a light-receiving unit.

Hereinafter, the components described above will be described in order.

The light-emitting device 4 included in the optical device 3 includes a light source 10, a spread angle narrowing member 20, a diffusion plate 30, a light-receiving element 40 (denoted as PD in FIG. 2) for monitoring light amount, and a driving unit 50. The light source 10, the spread angle narrowing member 20, the diffusion plate 30, and the light-receiving element 40 for monitoring light amount in the light-emitting device 4 will be described later. The spread angle narrowing member 20 is an example of a first optical member, and the diffusion plate 30 is an example of a second optical member.

The driving unit 50 in the light-emitting device 4 drives the light source 10. For example, the light source 10 is driven by the driving unit 50 so as to repeat emitting pulsed light at several tens of MHz to several hundreds of MHz. The light emitted by the light source 10 is referred to as emitted light, and pulsed light emitted from the light source 10 is referred to as emitted light pulse.

The 3D sensor 6 includes plural light-receiving regions arranged in a lattice pattern. The 3D sensor 6 receives pulsed light reflected from the measurement target in response to the emitted light pulse from the light source 10 of the light-emitting device 4. The light pulse received by the 3D sensor 6 is referred to as a received light pulse. Then, the 3D sensor 6 outputs, as a digital value for each light-receiving region, a signal corresponding to a time from when the light is emitted from the light source 10 to when the light reflected by the measurement target is received by the 3D sensor 6. For example, the 3D sensor 6 is configured as a device having a CMOS structure in which each light-receiving region includes two gates and two charge accumulating units corresponding to the gates. Then, the 3D sensor 6 is configured to alternately transfer photoelectrons generated in each light-receiving region by alternately applying pulses to the two gates to one of the two charge accumulating units, and to accumulate charges corresponding to a phase difference between the emitted light pulse and the received light pulse. Then, the digital value corresponding to the charges corresponding to the phase difference between the emitted light pulse and the received light pulse is output for each light-receiving region as a signal via an AD converter.

The 3D sensor 6 may include a condensing lens.

The shape identifying unit 81 of the optical device control unit 8 acquires a digital value obtained for each light-receiving region of the 3D sensor 6 from the 3D sensor 6. Then, the shape identifying unit 81 measures the three-dimensional shape of the measurement target by calculating a distance to the measurement target for each light-receiving region based on the acquired digital value. The shape identifying unit 81 identifies a three-dimensional image from the measured three-dimensional shape.

The authentication processing unit 91 of the system control unit 9 performs an authentication process related to use of the information processing device 1 when the three-dimensional image of the measurement target that is the identification result identified by the shape identifying unit 81 matches a three-dimensional image stored in advance in the ROM or the like. The authentication process related to the use of the information processing device 1 is, for example, a process of determining whether to permit the use of the information processing device 1, namely the own device. When the measurement target is a face, if a three-dimensional image of the face matches a three-dimensional image of a face stored in a storage member such as a ROM, the authentication processing unit 91 permits the use of the information processing device 1, including various applications provided by the information processing device 1.

The shape identifying unit 81 and the authentication processing unit 91 are constituted by a CPU that executes a program, for example. These functions may also be implemented by an integrated circuit such as an ASIC or an FPGA. Further, these functions may also be implemented by cooperation between a CPU that executes software such as a program and an integrated circuit.

Further, although the optical device 3, the optical device control unit 8, and the system control unit 9 are separately illustrated in FIG. 4, the system control unit 9 may include the optical device control unit 8. Further, the optical device control unit 8 may be included in the optical device 3. Further, the optical device 3, the optical device control unit 8, and the system control unit 9 may be integrated.

### Configuration of Optical Device 3

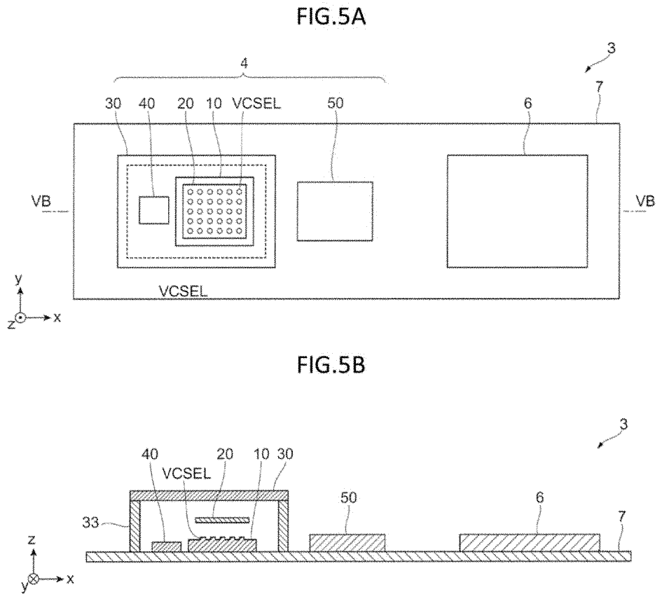

Next, the optical device 3 will be described in detail. FIGS. 5A and 5B illustrate an example of a plan view and a cross-sectional view of the optical device 3 to which the first exemplary embodiment is applied. FIG. 5A is a plan view, and FIG. 5B is a cross-sectional view taken along line VB-VB of FIG. 5A. Here, a lateral direction in FIG. 5A is defined as the x direction, an upper direction in FIG. 5A is defined as the y direction, and a front side direction perpendicular to a plane of FIG. 5A is defined as the z direction.

First, the plan view illustrated in FIG. 5A will be described.

In the optical device 3, the light-emitting device 4 and the 3D sensor 6 are arranged side by side in the x direction on a circuit board 7, for example. The circuit board 7 uses a plate-like member made of an insulating material as a base member, and the circuit board is provided with a conductor pattern made of a conductive material. The insulating material is, for example, ceramic, epoxy resin, or the like. The conductive material is, for example, a metal such as copper (Cu) or silver (Ag), or a conductive paste containing such a metal. The circuit board 7 may be a single-layer board having a conductor pattern provided on a front surface of the circuit board 7, or may be a multilayer board having plural layers of conductor patterns. The light-emitting device 4 and the 3D sensor 6 may be disposed on different circuit boards.

In the light-emitting device 4, the light-receiving element 40 for monitoring light amount, the light source 10, and the driving unit 50 are arranged side by side in the x direction on the circuit board 7, for example. Then, the spread angle narrowing member 20 is provided so as to cover the light source 10, and the diffusion plate 30 is provided so as to cover the light source 10 and the light-receiving element 40 for monitoring light amount covered with the spread angle narrowing member 20.

A planar shape of the light source 10, which is a shape in a planar view, is, for example, rectangular. The planar shape of the light source 10 may not be rectangular. A light-emitting direction (light-emitting side) of the light source 10 is the z direction. The light source 10 may be directly mounted on the circuit board 7, or may be mounted on the circuit board 7 via a heat dissipation base material such as aluminum oxide or aluminum nitride. When the heat dissipation base material is interposed between the light source 10 and the circuit board 7, electric power supplied to the light source 10 may be increased, and thus light output of the light source 10 may be increased. Hereinafter, the light source 10 will be described as being mounted directly on the circuit board 7. Here, the planar shape refers to a shape in a planar view, and the planar view refers to a view from the z direction in FIG. 5A. The same applies hereinafter. Here, the light output refers to a light flux.

The light source 10 includes a vertical cavity surface emitting laser (VCSEL). Hereinafter, the vertical cavity surface emitting laser VCSEL is referred to as the VCSEL. As will be described later, in the VCSEL, an active region serving as a light-emitting region is provided between a lower multilayer film reflector and an upper multilayer film reflector that are stacked on a board, and a laser beam is emitted in a direction perpendicular to the board. For this reason, plural VCSELs may be two-dimensionally arranged to be easily configured as a surface emitting light source. The light source 10 is formed by integrating the plural

VCSELs as one semiconductor component. The number of VCSELs illustrated in FIG. 5A is an example. Then, the VCSEL is an example of a light-emitting element.

The spread angle narrowing member 20 covering the light source 10 is an optical member having a light transmitting property of transmitting light emitted from each of the plural VCSELs included in the light source 10 (hereinafter, referred to as emitted light) and a function of narrowing a spread angle of the emitted light of each of the VCSELs. When light is emitted from the emission surface, the VCSEL emits light at a spread angle determined by the structure. That is, an irradiation region of the emitted light on a plane parallel to the emission surface increases as the distance from the emission surface increases. Therefore, the spread angle narrowing member 20 narrows the spread angle of the light emitted from the VCSEL and emits the light. Therefore, the optical member is referred to as the spread angle narrowing member 20. Here, the spread angle refers to an angle range in which the light intensity is l/e² of the maximum value in the irradiation region on the plane parallel to the emission surface. The spread angle of the emitted light may be evaluated in an angle range or the like which is the full width at half maximum (FWHM) of the light intensity.

The diffusion plate 30 is, for example, a member having a rectangular planar shape. The diffusion plate 30 diffuses and emits light incident on the diffusion plate 30. At this time, the diffusion plate 30 changes directivity of the light incident on the diffusion plate 30 from the spread angle narrowing member 20 and emits the light. That is, the diffusion plate 30 emits light so as to have a light intensity distribution different from the light intensity distribution when the light emitted from the spread angle narrowing member 20 (at the time of emission) is emitted to the irradiated surface 310 without passing through the diffusion plate 30. For example, since the light source 10 has a small size as described later, the light source 10 may be regarded as a point light source. The diffusion plate 30 changes the irradiation pattern of the light incident from the light source 10 via the spread angle narrowing member 20 to the irradiation pattern on the irradiated surface 310 as illustrated in FIG. 3A.

A size of the diffusion plate 30 may be set such that, for example, a lateral width and a vertical width are 1 mm to 10 mm, and a thickness is 0.1 mm to 1 mm. The diffusion plate 30 may cover the light source 10 covered with the spread angle narrowing member 20 and the light-receiving element 40 for monitoring light amount in a planar view. Further, although an example in which the diffusion plate 30 has the rectangular shape in the planar view is described in FIG. 5A, the diffusion plate 30 may have another shape such as a polygonal shape or a circular shape. Then, when the diffusion plate 30 has the size and the shape as described above, the diffusion plate 30 suitable for face authentication of the portable information processing terminal and three-dimensional shape measurement at a relatively short distance of about several meters is provided.

Next, the cross-sectional view illustrated in FIG. 5B will be described.

The spread angle narrowing member 20 is held by a support member (not illustrated) on the z direction side, which is the light-emitting side of the VCSEL included in the light source 10. The spread angle narrowing member 20 is held by the support member at a position separated by a predetermined distance from the emission surface of the VCSEL included in the light source 10.

The diffusion plate 30 is supported by a side wall 33 on the z direction side, which is the light-emitting side of the light source 10. The side wall 33 is provided so as to surround the spread angle narrowing member 20 covering the light source 10 and the light-receiving element 40 for monitoring light amount. The diffusion plate 30 is held by the side wall 33 at a predetermined distance from the spread angle narrowing member 20 covering the light source 10 and the light-receiving element 40 for monitoring light amount. Then, the light incident on the diffusion plate 30 from the light source 10 via the spread angle narrowing member 20 is emitted from the diffusion plate 30 and is emitted to the irradiated surface 310 (see FIG. 2).

When the side wall 33 is formed of a member that absorbs the light emitted from the light source 10, the light emitted from the light source 10 is prevented from passing through the side wall 33 and being radiated to outside. Further, since the light source 10, the spread angle narrowing member 20, and the light-receiving element 40 for monitoring light amount are sealed by the diffusion plate 30 and the side wall 33, dust prevention, moisture prevention, or the like are achieved. In the first exemplary embodiment, the light source 10 including the spread angle narrowing member 20 and the light-receiving element 40 for monitoring light amount are disposed close to each other, such that the light source 10 and the light-receiving element 40 for monitoring light amount may be easily surrounded by the side wall 33 that has a small size, and thus the diffusion plate 30 is sufficient with a small size.

The light-receiving element 40 for monitoring light amount is a device that outputs an electric signal corresponding to an amount of received light (hereinafter, referred to as the received light amount). The light-receiving element 40 for monitoring light amount is, for example, a photodiode (PD) made of silicon or the like. The light-receiving element 40 for monitoring light amount is configured to receive light emitted from the light source 10 via the spread angle narrowing member 20 and reflected by a back surface of the diffusion plate 30, that is, a surface on the −z direction side of the diffusion plate 30.

The light source 10 is controlled based on the received light amount of the light-receiving element 40 for monitoring light amount so as to maintain predetermined light output. That is, the optical device control unit 8 controls the light source 10 via the driving unit 50 based on the received light amount of the light-receiving element 40 for monitoring light amount. When the received light amount of the light-receiving element 40 for monitoring light amount is extremely low, the diffusion plate 30 may be detached or damaged, and the light emitted from the light source 10 via the spread angle narrowing member 20 may be directly emitted to the outside without being diffused by the diffusion plate 30. In such a case, the optical device control unit 8 reduces the light output of the light source 10 via the driving unit 50. For example, the optical device control unit 8 stops emission of the light from the light source 10.

### Configuration of Light Source 10

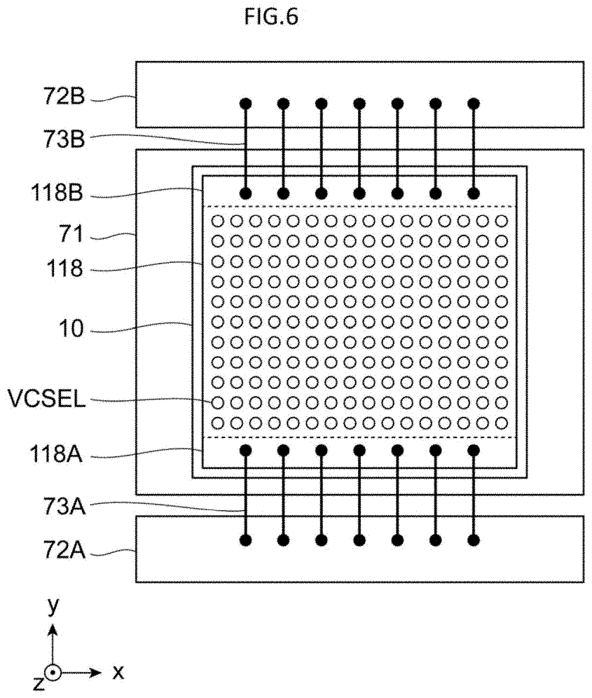

FIG. 6 illustrates an example of a plan view of the light source 10. Here, a cathode pattern 71 and anode patterns 72A and 72B, which are conductor patterns provided on the circuit board 7, and bonding wires 73A and 73B that connect the light source 10 and these conductor patterns are collectively illustrated. The number of VCSELs illustrated in FIG. 6 is an example.

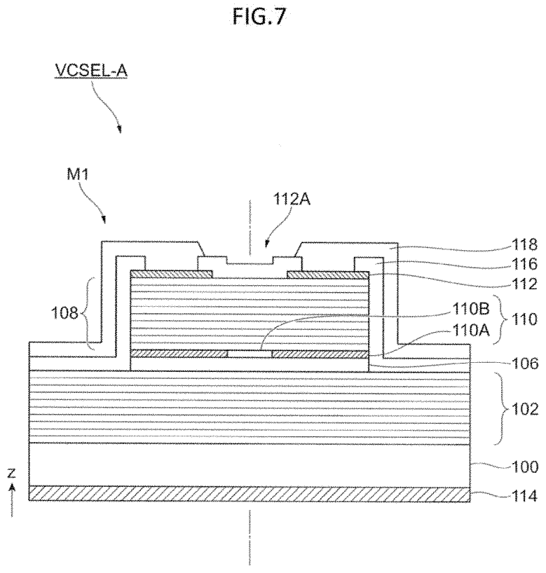

As described above, the light source 10 is formed by integrating the plural VCSELs. Then, a cathode electrode 114 is provided on the back surface of the light source 10 (see FIG. 7 described later), and an anode electrode 118 is provided on the front surface of the light source 10. The anode electrode 118 includes a portion connecting p-side electrodes 112 of the plural VCSELs, a pad portion 118A to which the bonding wire 73A to be described later is connected, and a pad portion 118B to which the bonding wire 73B is connected. That is, the plural VCSELs are connected in parallel.

In FIG. 6, the plural VCSELs in the light source 10 are arranged at each lattice point of a lattice formed in a square shape, for example. The plural VCSELs may be arranged in another array such as an array in which positions at which the VCSELs are arranged for each row are shifted by a half pitch.

The cathode pattern 71 and the anode patterns 72A and 72B are provided as conductor patterns on the circuit board 7. The cathode pattern 71 is formed to have a larger area than the light source 10 such that the cathode electrode 114 provided on the back surface of the light source 10 is connected thereto. Then, the cathode electrode 114 provided on the back surface of the light source 10 is bonded to the cathode pattern 71 on the circuit board 7 using a conductive adhesive. Then, the pad portion 118A of the anode electrode 118 of the light source 10 is connected to the anode pattern 72A on the circuit board 7 by the bonding wire 73A, and the pad portion 118B of the anode electrode 118 of the light source 10 is connected to the anode pattern 72B on the circuit board 7 by the bonding wire 73B.

The number of VCSELs included in the light source 10 is, for example, 10 to 1000. The plural VCSELs forming the light source 10 are connected in parallel and driven in parallel. That is, the plural VCSELs simultaneously emit light. The light source 10 is, for example, 0.5 mm square to 3 mm square. When irradiating a farther object to be irradiated, the number of VCSELs may be further increased.

As described above, the light source 10 emits the light in order to measure the three-dimensional shape of the measurement target. During the above-described user authentication based on the shape of the face, a measurement distance is about 10 cm to about 1 m. Thus, a length of one side of the detection range I is about 1 m. Since the light source 10 is required to irradiate the detection range I with light having predetermined light intensity, the VCSELs forming the light source 10 are required to have large light output. As an example, in the light source 10 in which 500 VCSELs are integrated, 4 mW to 8 mW is required as the light output of one VCSEL. Therefore, 2 W to 4 W are required as the light output of the light source 10.

In the first exemplary embodiment, a VCSEL that oscillates in a multiple transverse mode is used as the VCSEL included in the light source 10. The multiple transverse mode may be referred to as a multi-mode. Therefore, the VCSEL that oscillates in the multiple transverse mode is referred to as a multi-mode VCSEL. A single transverse mode may be referred to as a single-mode. Therefore, the VCSEL that oscillates in the single transverse mode is referred to as a single-mode VCSEL. The multi-mode VCSEL has a larger oxidation aperture diameter than that of the single-mode VCSEL, and thus has larger light output. However, a spread angle of emitted light of the multi-mode VCSEL is larger than that of the single-mode VCSEL. As will be described later, the larger the spread angle of the light incident on the diffusion plate 30 is, the larger the amount of light emitted to the skirt range II is. That is, when the light emitted from the multi-mode VCSEL is directly incident on the diffusion plate 30, the amount of ineffective wasteful light emitted to the skirt range II increases. Therefore, in the first exemplary embodiment, the spread angle narrowing member 20 is provided to narrow the spread angle of the light emitted from the multi-mode VCSEL included in the light source 10, and the light is incident on the diffusion plate 30.

### Multiple Transverse Mode VCSEL (VCSEL-A) Having λ Resonator Structure

As an example, a multi-mode VCSEL having a λ resonator structure included in the light source 10 to which the first exemplary embodiment is applied will be described. In order to distinguish from a single-mode VCSEL having a long resonator structure to be described later, the multi-mode VCSEL having the λ resonator structure is referred to as VCSEL-A, and the single-mode VCSEL having the long resonator structure is referred to as VCSEL-B.

FIG. 7 illustrates a cross-sectional structure of the multi-mode VCSEL (VCSEL-A) having the λ resonator structure that forms the light source 10. An upper direction in FIG. 7 is the z direction.

The VCSEL-A is implemented by sequentially stacking on a semiconductor substrate 100 such as an n-type GaAs, an n-type lower distributed Bragg reflector (DBR) 102 in which AlGaAs layers having different Al compositions are alternately stacked, an active region 106 including a quantum well layer sandwiched between an upper spacer layer and a lower spacer layer, and a p-type upper distributed Bragg reflector 108 in which AlGaAs layers having different Al compositions are alternately stacked. Hereinafter, the distributed Bragg reflector is referred to as a DBR.

The n-type lower DBR 102 is a laminate of a pair of an Al_{0.9}Ga_{0.1}As layer and a GaAs layer, a thickness of each layer is λ/4n, (λ is an oscillation wavelength, and nᵣ is a refractive index of a medium), and these layers are alternately stacked in 40 cycles. A carrier concentration after doping with silicon, which is an n-type impurity, is, for example, 3×10¹⁸ cm⁻³.

The active region 106 is formed by stacking the lower spacer layer, the quantum well active layer, and the upper spacer layer. For example, the lower spacer layer is an undoped Al_{0.6}Ga_{0.4}As layer, the quantum well active layer is an undoped InGaAs quantum well layer and an undoped GaAs barrier layer, and the upper spacer layer is an undoped Al_{0.6}Ga_{0.4}As layer.

The p-type upper DBR 108 is a laminate of a pair of a p-type Al_{0.9}Ga_{0.1}As layer and a GaAs layer, a thickness of each layer is λ/4nᵣ, and these layers are alternately stacked in 29 cycles. A carrier concentration after doping with carbon, which is a p-type impurity, is, for example, 3×10¹⁸ cm⁻³. A contact layer made of p-type GaAs may be formed on the uppermost layer of the upper DBR 108, and a current confinement layer 110 made of p-type AlAs is formed on the lowermost layer of the upper DBR 108 or inside the upper DBR 108.

By etching the semiconductor layer stacked from the upper DBR 108 to the lower DBR 102, a cylindrical mesa M1 is formed on the semiconductor substrate 100. Accordingly, the current confinement layer 110 is exposed at a side surface of the mesa M1. By an oxidation process, an oxidized region 110A oxidized from the side surface of the mesa M1 and a conductive region 110B surrounded by the oxidized region 110A are formed in the current confinement layer 110. In the oxidation process, an AlAs layer has a higher oxidation rate than an AlGaAs layer, and the oxidized region 110A is oxidized from the side surface toward an inner side of the mesa M1 at a substantially constant rate, such that a planar shape of the conductive region 110B is a shape that reflects an outer shape of the mesa M1, that is, a circular shape, and a center of the shape substantially coincides with an axial direction of the mesa M1 indicated by a dashed-dotted line. The mesa M1 has a columnar structure. The semiconductor layer from the upper DBR 108 to the lower DBR 102 is stacked by epitaxy. Therefore, this semiconductor layer may be referred to as an epitaxial layer.

The annular p-side electrode 112 in which Ti, Au and the like are stacked is formed on the uppermost layer of the mesa M1. The p-side electrode 112 is in ohmic contact with the contact layer provided in the upper DBR 108. The front surface of the upper DBR 108 inside the annular p-side electrode 112 serves as a light emission port 112A through which a laser beam is emitted to the outside. That is, in the VCSEL-A, light is emitted in a direction perpendicular to the semiconductor substrate 100, and the axial direction of the mesa M1 is an optical axis. Further, the cathode electrode 114 is formed as an n-side electrode on a back surface of the semiconductor substrate 100. A front surface of the upper DBR 108 inside the p side electrode 112 is a light-emitting surface. That is, the optical axis direction of the VCSEL-A is the light-emitting direction.

Then, an insulating layer 116 is provided in a manner of covering a front surface of the mesa M1 except for a portion of the p side electrode 112 to which an anode electrode (the anode electrode 118 to be described later) is connected and the light emission port 112A. Then, the anode electrode 118 is provided to be in ohmic contact with the p-side electrode 112 except for the light emission port 112A. The anode electrode 118 is shared by plural VCSEL-As. That is, in the plural VCSEL-As forming the light source 10, the p-side electrodes 112 thereof are connected in parallel by the anode electrode 118. As described above, the anode electrode 118 is provided as a continuous electrode pattern covering a region between each VCSEL-A except for the light emission port 112A of each VCSEL-A. Therefore, a pattern having a larger area is formed as compared with a case where drive wiring is individually provided for each VCSEL-A, and a voltage drop is prevented when a drive current flows.

### Relationship between Spread Angle of Light Emitted from VCSEL-A and skirt Spread Amount in Light Intensity Distribution

Here, a relationship between the spread angle of the light emitted from the VCSEL-A included in the light source 10 and the above-described skirt spread amount in the case where the spread angle narrowing member 20 is not used will be described.

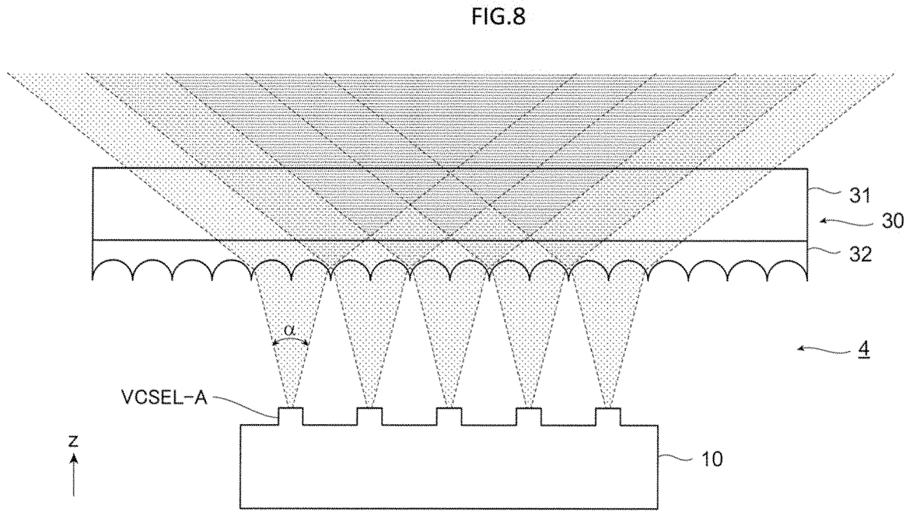

FIG. 8 schematically illustrates a spread angle a of the light emitted from the multi-mode VCSEL (VCSEL-A).

The diffusion plate 30 includes, for example, a flat glass base material 31 whose two surfaces are parallel to each other, and a resin layer 32 in which plural minute concave portions and convex portions for diffusing light are formed on a front surface on one side of the glass base material 31. Then, the diffusion plate 30 is provided on a path (referred to as a light-emitting path) of the light emitted from the VCSEL-A included in the light source 10, and diffuses and emits the light emitted from the VCSEL-A by the concave portions and the convex portions of the resin layer 32. At this time, at least one of the plural concave portions or convex portions has, for example, a width of 10 μm or more and 100 μm or less and a height (depth) of 1 μm or more and 50 μm or less. Further, the plural concave portions and convex portions may be a pattern having a pitch, or may be a random pattern having no pitch. In the diffusion plate 30, a refraction direction of the light is controlled by the pattern of the plural concave portions and convex portions, and the light emitted from the light source 10 is shaped into a desired irradiation pattern. The pattern of the concave portions and the convex portions may be referred to as a lens pattern. Here, the light emitted from the VCSEL-A of the light source 10 has the spread angle α. The diffusion plate 30 superimposes the light emitted from each VCSEL-A and emit the light.

In the diffusion plate 30, by the plural concave portions and convex portions formed in the resin layer 32, an irradiation pattern having a side length of about 1 m as illustrated in FIG. 3A is formed from the light emitted from the light source 10 which may be regarded as a substantially point light source having a side length of, for example, 0.5 to 3 mm. Since the resin layer 32 of the diffusion plate 30 transmits the light emitted from the VCSEL, a decrease in light use efficiency due to absorption is prevented. Further, since the pattern of the plural concave portions and convex portions is easily manufactured by a mold formed in advance, it is possible to reduce the cost of the light-emitting device.

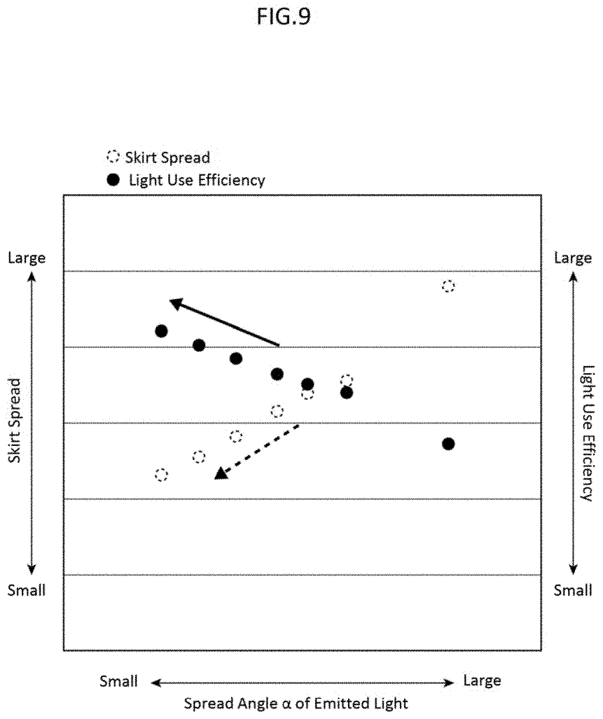

FIG. 9 illustrates a relationship between the spread angle α of the light emitted from the VCSEL-A, the skirt spread amount, and the light use efficiency on the irradiated surface 310. These relationships are obtained by simulation.

As illustrated in FIG. 9, as the spread angle α of the emitted light decreases, the skirt spread amount on the irradiated surface 310 increases, and the light use efficiency is improved. This is because light with various incident angles is incident on the diffusion plate 30 when the spread angle of the light emitted from the light source 10 is large as compared with a case where the spread angle is small, and thus a range of an angle of refraction is widened due to the lens pattern of the diffusion plate 30. That is, as the spread angle of the light emitted from the light source 10 increases, the angle of refraction takes more various values. Then, the light emitted from the diffusion plate 30 is less likely to be shaped into a desired irradiation pattern, and when the irradiation pattern is a quadrangular shape, the quadrangular shape is blurred. That is, as the spread angle of the light emitted from the light source 10 increases, the skirt spread amount increases. That is, the diffusion plate 30 is configured such that the skirt spread amount is the smallest when the parallel light is incident.

In the measurement of the three-dimensional shape by a TOF method in which the light source 10 having large light output is required, reducing of the skirt spread amount, that is, narrowing of the wasteful skirt range II which is not used in the three-dimensional measurement contributes to the improvement of the light use rate of the light source 10. Accordingly, by narrowing the skirt range II, that is, by reducing the skirt spread amount, the light use efficiency is improved, and the power consumption of the light source 10 is reduced as compared with a case where the skirt spread amount is not reduced.

Therefore, in the light-emitting device 4 to which the first exemplary embodiment is applied, the spread angle narrowing member 20 is provided between the light source 10 and the diffusion plate 30 to narrow the spread angle α of the light emitted from the VCSEL-A included in the light source 10 and emit the light toward the diffusion plate 30.

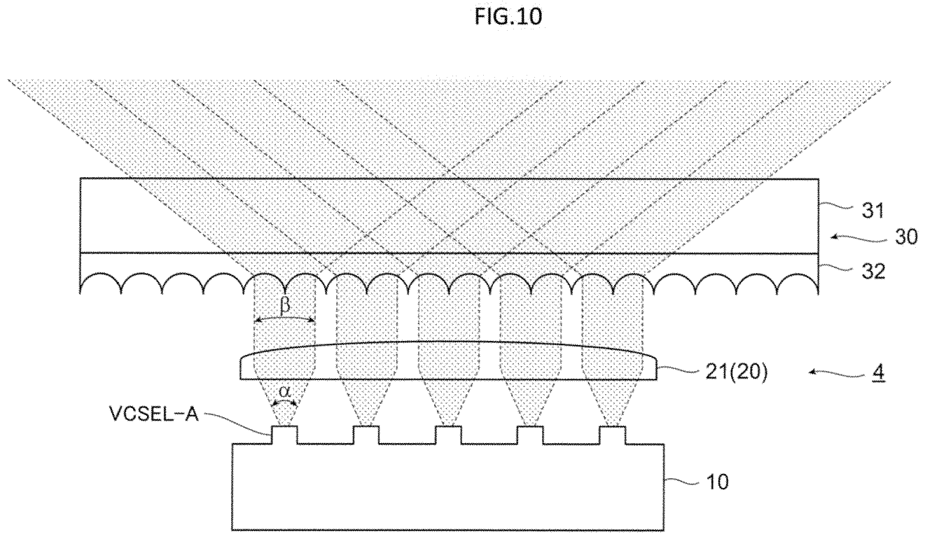

FIG. 10 schematically illustrates a relationship among the light source 10 in the light-emitting device 4 to which the first exemplary embodiment is applied, a convex lens 21 as an example of the spread angle narrowing member 20, and the diffusion plate 30. In the light-emitting device 4 to which the first exemplary embodiment is applied, the spread angle narrowing member 20 is the convex lens 21 held between the light source 10 and the diffusion plate 30. In FIG. 10, the convex lens 21, which is an example of the spread angle narrowing member 20, is referred to as 21 (20). The same applies to other cases.

The light emitted from the VCSEL-A having the spread angle α and incident on the convex lens 21 is emitted from the convex lens 21 at a spread angle β smaller than the spread angle α(β<α). That is, a center of the spread angle β is shifted from a center of the spread angle α toward the light source 10. In FIG. 10, the light emitted from the convex lens 21 is illustrated as parallel light in all the VCSEL-As. In the case of parallel light, βis “0”. The light emitted from the convex lens 21 may not be parallel light, and may be different for each VCSEL-A. That is, when one convex lens 21 provided so as to cover all the VCSEL-As of the light source 10 is used, an effect of narrowing the spread angle due to an aberration between a central portion and a peripheral portion of the convex lens 21 is different. Therefore, the spread angle β is different for each VCSEL-A. Even when the spread angle β is different for each VCSEL-A, the spread angle α is narrowed to the spread angle β by the convex lens 21 and is incident on the diffusion plate 30.

As described above, when the convex lens 21 is used as the spread angle narrowing member 20, the VCSEL-A included in the light source 10 may be regarded as emitting light at the spread angle β smaller than the spread angle α. Therefore, as illustrated in FIG. 9, the skirt spread amount on the irradiated surface 310 is small.

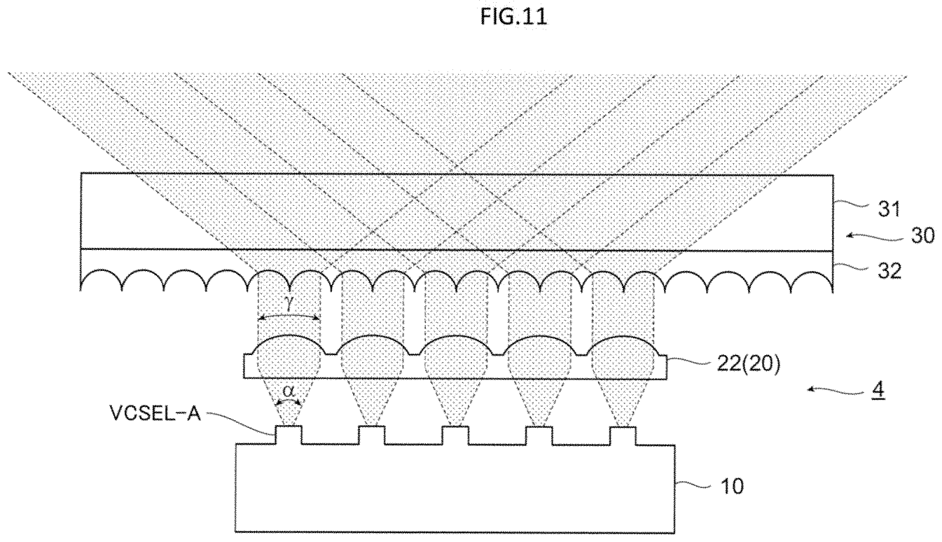

FIG. 11 schematically illustrates a relationship among the light source 10 in the light-emitting device 4 to which the first exemplary embodiment is applied, a fly-eye lens 22 as another example of the spread angle narrowing member 20, and the diffusion plate 30. Here, the spread angle narrowing member 20 is the fly-eye lens 22 held between the light source 10 and the diffusion plate 30.

The fly-eye lens 22 includes plural convex lenses provided corresponding to the VCSEL-A, respectively. The fly-eye lens 22 emits light incident from the VCSEL-A at a spread angle γ smaller than the spread angle a of the light emitted from the VCSEL-A. When the fly-eye lens 22 is provided corresponding to each of the VCSEL-As, it is easy to control the light-emitting direction of the light emitted from the spread angle narrowing member 20 as compared with the case where the convex lens 21 is used.

Even when the fly-eye lens 22 is used as the spread angle narrowing member 20, the VCSEL-A included in the light source 10 may be regarded as emitting light at the spread angle y smaller than the spread angle α. Therefore, as illustrated in FIG. 9, the skirt spread amount on the irradiated surface 310 is small. The fly-eye lens 22 may be configured such that one convex lens corresponds to the plural VCSEL-As.

In the above description, the convex lens 21 and the fly-eye lens 22 have been described as examples of the spread angle narrowing member 20. The spread angle narrowing member 20 is not limited thereto, and may be applied as long as the spread angle narrowing member 20 is held between the light source 10 and the diffusion plate 30 and narrows the spread angle of the light emitted from the VCSEL-A.

### Second Exemplary Embodiment

In the first exemplary embodiment, the spread angle narrowing member 20 is held between the light source 10 and the diffusion plate 30 and narrows the spread angle of the light emitted from the VCSEL-A. In the light-emitting device 4 to which a second exemplary embodiment is applied, the spread angle narrowing member 20 is provided on the light-emitting surface of the light source 10. Since the other configurations are the same as those of the first exemplary embodiment, the description thereof will be omitted.

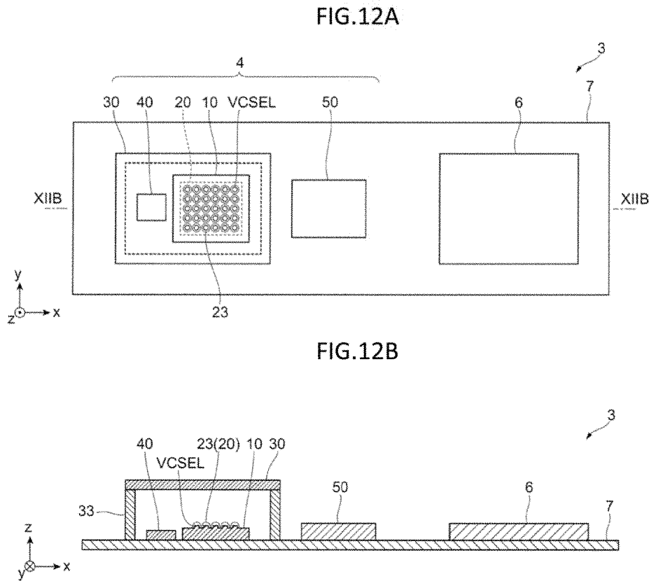

FIG. 12A is a plan view of the optical device 3 to which the second exemplary embodiment is applied, and FIG. 12B is a cross-sectional view taken along line XIIB-XIIB of FIG. 12A. Here, a lateral direction in FIG. 12A is defined as the x direction, an upper direction in FIG. 12A is defined as the y direction, and a front side direction perpendicular to a plane of FIG. 12A is defined as the z direction.

As illustrated in FIGS. 12A and 12B, in the optical device 3 to which the second exemplary embodiment is applied, the spread angle narrowing member 20 is provided on the light source 10 in the light-emitting device 4. Except for this, the configuration of the optical device 3 to which the second exemplary embodiment is applied is the same as that of the optical device 3 to which the first exemplary embodiment illustrated in FIG. 5A is applied. Therefore, the same components are denoted by the same reference numerals, the description thereof will be omitted, and different components will be described.

As illustrated in FIG. 12B, in the light-emitting device 4 according to the second exemplary embodiment, the spread angle narrowing member 20 is an array of microlenses 23, and is provided on the VCSEL-A included in the light source 10. Then, each microlens 23 is provided corresponding to each VCSEL-A. As illustrated in FIG. 12A, an outer edge of the microlens 23 in a planar view is circular. When the microlens 23 is provided corresponding to each VCSEL-A, it is easy to control the light-emitting direction of the light emitted from the spread angle narrowing member 20.

An array of the microlenses 23 is formed by heating a photoresist or the like provided on the VCSEL-A to cause viscous flow. That is, the microlenses 23 are formed in a semiconductor manufacturing process for manufacturing the light source 10. The microlenses 23 may be connected by the same material as the material forming the microlenses 23.

In the case where the spread angle narrowing member 20 described in the first exemplary embodiment is the fly-eye lens 22, the light source 10 and the fly-eye lens 22 are configured as separate members. Therefore, when assembling the optical device 3 or the light-emitting device 4, a positional relationship between each convex lens of the fly-eye lens 22 and the VCSEL-A included in the light source 10 is mechanically matched. Further, the fly-eye lens 22 may be shifted or detached from the light source 10.

When the spread angle narrowing member 20 is the array of the microlenses 23, the array of the microlenses 23 is formed by the semiconductor manufacturing process, and therefore, compared to the case of the fly-eye lens 22, a positional relationship between the VCSEL-A and the microlenses 23 may be more accurately set. Further, the array of the microlenses 23 is unlikely to be detached or shifted from the light source 10. Further, since the spread angle narrowing member 20 (the array of the microlenses 23) is formed on the light source 10, the light-emitting device 4 is downsized.

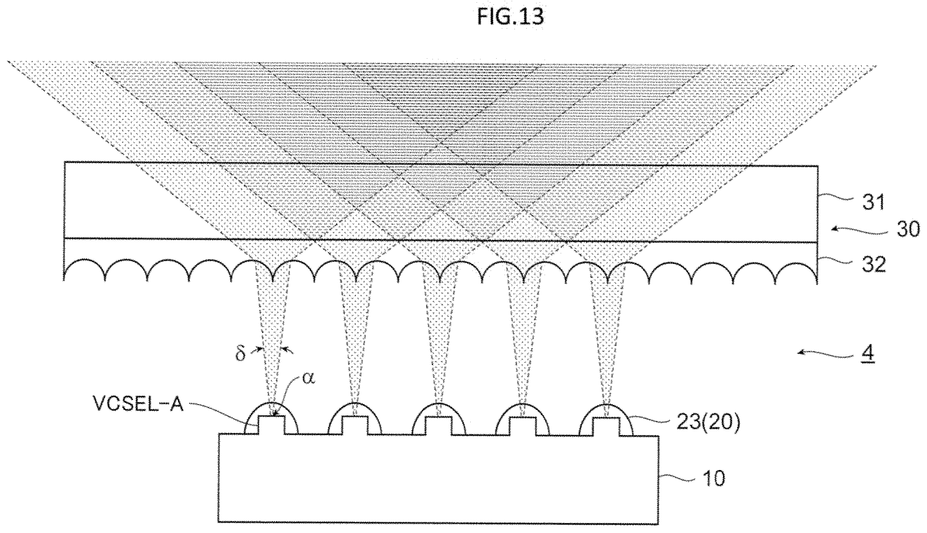

FIG. 13 schematically illustrates a relationship among the light source 10 in the light-emitting device 4 to which the second exemplary embodiment is applied, the array of the microlenses 23 as an example of the spread angle narrowing member 20, and the diffusion plate 30.

The light emitted from the VCSEL-A has the spread angle α. The emitted light is incident on the microlenses 23 and is emitted as light having a spread angle δ smaller than the spread angle a illustrated in FIG. 8 (δ<α). It is assumed that the irradiation region of the light emitted from the microlenses 23 on a plane perpendicular to the light-emitting direction gradually increases or a size of the irradiation region is constant as a distance from the VCSEL-A toward the diffusion plate 30 increases. The light having the spread angle δ is incident on the diffusion plate 30.

Even when the array of the microlenses 23 is used as the spread angle narrowing member 20, the VCSEL-A included in the light source 10 may be regarded as emitting light at the spread angle δ smaller than the spread angle α. Therefore, as illustrated in FIG. 9, the skirt spread amount on the irradiated surface 310 is small. One microlens 23 may be configured to correspond to the plural VCSEL-A.

Here, it is assumed that the irradiation region of the light emitted from the microlenses 23 on the plane perpendicular to the light-emitting direction gradually increases or the size of the irradiation region is constant as the distance from the VCSEL-A toward the diffusion plate 30 increases. Depending on a curvature of the front surface of the microlens 23, a distance from the light-emitting surface of the VCSEL-A to the surface of the microlens 23, or the like, the microlens 23 may be configured such that the light emitted from the microlens 23 converges on a certain point in the light-emitting direction. However, when the microlens 23 is configured to converge the emitted light, a diameter (referred to as a spot diameter) of the light irradiation region on the diffusion plate 30 is reduced, and a size of the light irradiation region may be substantially the same as a size of the pattern of the concave portions and the convex portions provided on the diffusion plate 30. In the diffusion plate 30, when light is not incident on a wide irradiation region including plural concave portions and convex portions, it is difficult to form the quadrangular irradiation pattern as illustrated in FIG. 3A on the irradiated surface 310. Therefore, the microlens 23 may be configured not to converge the light in the light-emitting direction of the VCSEL-A.

Then, the pattern of the plural concave portions and convex portions of the diffusion plate 30 is configured such that, when parallel light is incident on the diffusion plate 30 as described above, the skirt spread amount is the smallest. Therefore, the light emitted from the microlens 23 may be parallel light, that is, collimated light. Here, the parallel light refers to a case where a spread angle ε is 0° or more and 5° or less, and the spread angle ε may be 0° or more and 2° or less. The same applies to the convex lens 21 and the fly-eye lens 22 which are the spread angle narrowing members 20 in the first exemplary embodiment.

In the above description, a center of the microlens 23, that is, a center of the convex portion is on the optical axis of the VCSEL-A, but the center of the microlens 23 may be set at a position shifted from the optical axis of the VCSEL-A. Accordingly, the direction of the light emitted from the microlens 23 is shifted from the optical axis direction of the VCSEL-A.

In the above description, the VCSEL included in the light source 10 is the multi-mode VCSEL (VCSEL-A) having the λ resonator structure. This is because the multi-mode VCSEL having the λ resonator structure may obtain a large oxidation aperture diameter as compared with the single-mode VCSEL having the λ resonator structure, and thus large light output may be obtained. However, the multi-mode VCSEL has a spread angle of emitted light larger than that of the single-mode VCSEL. Therefore, when the single-mode VCSEL having large light output is used, the spread angle of the light emitted from the spread angle narrowing member 20 may be further reduced as compared with the case of using the multi-mode VCSEL.

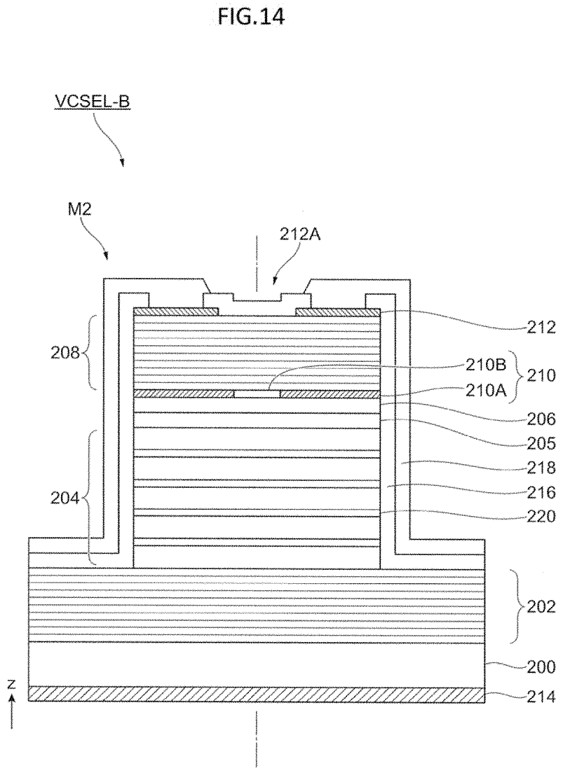

Hereinafter, as a modification of the light source 10 of the light-emitting device 4 to which the second exemplary embodiment is applied, a case where a light source 10′ including a single transverse mode (single-mode) VCSEL having a long resonator structure is used will be described. In the VC SEL having the long resonator structure, a spacer layer of several λ to several tens of λ is introduced between an active region in a VCSEL having a general λ resonator structure whose resonator length is an oscillation wavelength λ and one multilayer film reflector so as to increase the resonator length and thus increase a loss in a high-order transverse mode. Accordingly, single mode oscillation may be performed with an oxidation aperture diameter larger than an oxidation aperture diameter of the VCSEL having the general λ resonator structure. In a VCSEL having a typical λ resonator structure, since a longitudinal mode interval (may be referred to as a free spectrum range) is large, a stable operation may be obtained by a single longitudinal mode. On the other hand, in the case of the VCSEL having the long resonator structure, a longitudinal mode interval is narrowed since the resonator length is increased, and standing waves, namely plural longitudinal modes, are present in a resonator, and as a result, switching between the longitudinal modes is likely to occur. Therefore, in the VCSEL having the long resonator structure, a layer that prevents the switching between the longitudinal modes (a layer 220 causing optical loss in FIG. 14 to be described later) is provided. The single-mode VCSEL having the long resonator structure is more likely to have a narrower spread angle as compared with the general single-mode VCSEL having the λ resonator structure. The single transverse mode refers to a mode in which a light intensity distribution of emitted light whose spread angle serves as a parameter has a unimodal characteristic, that is, a characteristic of having one light intensity peak. Here, a mode including plural transverse modes within a range in which the unimodal characteristic is maintained is also referred to as a single transverse mode.

### Single Mode VCSEL (VCSEL-B) Having Long Resonator Structure

FIG. 14 illustrates a cross-sectional structure of a single-mode VCSEL having a single long resonator structure that forms the light source 10′. As described above, the single-mode VCSEL having the long resonator structure is referred to as VCSEL-B. An upper direction in FIG. 14 is the z direction.

The VCSEL-B is formed by stacking, on an n-type GaAs board 200, an n-type lower DBR 202 in which AlGaAs layers having different Al compositions are alternately stacked, a resonator extended region 204 formed on the lower DBR 202 and extending a resonator length, an n-type carrier block layer 205 formed on the resonator extended region 204, an active region 206 formed on the carrier block layer 205 and including a quantum well layer sandwiched between an upper spacer layer and a lower spacer layer, and a p-type upper DBR 208 that is formed on the active region 206 and in which AlGaAs layers having different Al compositions are alternately stacked. A p-type AlAs current confinement layer 210 is formed on the lowermost layer of the upper DBR 208 or in the upper DBR 208.

Since the lower DBR 202, the active region 206, the upper DBR 208, and the current confinement layer 210 are the same as the lower DBR 102, the active region 106, the upper DBR 108, and the current confinement layer 110 of the VCSEL-A illustrated in FIG. 7, description thereof will be omitted.

The resonator extended region 204 is a monolithic layer formed by a series of epitaxial growth. Therefore, the resonator extended region 204 is made of AlGaAs, GaAs, or AlAs whose lattice constant coincides or matches that of a GaAs board. Here, the resonator extended region 204 is made of AlGaAs that does not cause light absorption so as to emit a laser beam in a 940 nm band. A film thickness of the resonator extended region 204 is set to 2 μm to 5 μm, and is set to 5λ, to 20λ, relative to the oscillation wavelength λ. Therefore, a movement distance of a carrier is increased. Therefore, the resonator extended region 204 may be an n-type region having a high carrier mobility, and thus the resonator extended region 204 is inserted between the n-type lower DBR 202 and the active region 206. Such the resonator extended region 204 may be referred to as a cavity extended region or a cavity space.

The carrier block layer 205 that has a large band gap and is made of, for example, Al_{0.9}Ga_{0.1}As, is formed between the resonator extended region 204 and the active region 206. Carrier leakage from the active region 206 is prevented and light emission efficiency is improved by inserting the carrier block layer 205. As will be described later, since the layer 220 causing optical loss, in which oscillation intensity of a laser beam is slightly attenuated, is inserted into the resonator extended region 204, the carrier block layer 205 plays a role of compensating for such loss. For example, a film thickness of the carrier block layer 205 is λ/4 mnᵣ (λ is the oscillation wavelength, m is an integer, and nᵣ is the refractive index of the medium).

A cylindrical mesa M2 is formed on the board 200 by etching stacked semiconductor layers from the upper DBR 208 to the lower DBR 202. The current confinement layer 210 is exposed on a side surface of the mesa M2. An oxidized region 210A selectively oxidized from the side surface of the mesa M2 and a conductive region 210B surrounded by the oxidized region 210A are formed in the current confinement layer 210. The conductive region 210B is an oxide aperture. A planar shape of the conductive region 210B parallel to the board is a shape that reflects an outer shape of the mesa M2, that is, a circular shape, and a center of the shape coincides with an axial direction of the mesa M2 indicated by a dashed-dotted line. In the single-mode VCSEL having the long resonator structure, a diameter of the conductive region 210B for obtaining the single transverse mode (single-mode) may be easily made larger than that of the single-mode VCSEL having the general λ resonator structure, and for example, the diameter of the conductive region 210B may be increased to 7 μm to 8 μm. The semiconductor layers from the upper DBR 208 to the lower DBR 202 are stacked by epitaxy. Therefore, these semiconductor layers may be referred to as an epitaxial layer.

An annular p-side electrode 212 made of a metal in which Ti, Au, and the like is stacked is formed on the uppermost layer of the mesa M2. The p-side electrode 212 is in ohmic contact with a contact layer of the upper DBR 208. An inner side of the annular p-side electrode 212 serves as a light emission port 212A through which a laser beam is emitted to the outside. That is, the axial direction of the mesa M2 is an optical axis. A front surface of the upper DBR 208 including the light emission port 212A is an emission surface. Further, a cathode electrode 214 that serves as an n-side electrode is formed on a back surface of the board 200.

Then, an insulating layer 216 is provided in such a manner that a front surface of the mesa M2 is covered except for a portion where the p-side electrode 212 and an anode electrode 218 to be described later are connected and the light emission port 212A. Then, the anode electrode 218 is provided to be in ohmic contact with the p-side electrode 212 except for the light emission port 212A. The anode electrode 218 is provided at a position except for a position where the light emission port 212A of each of plural VCSEL-Bs is located. That is, in the plural VCSEL-Bs included in the light source 10, the respective p-side electrodes 212 are connected in parallel by the anode electrode 218. As described above, the anode electrode 218 is provided as a continuous electrode pattern covering a region between each VCSEL-B except for the light emission port 212A of each VCSEL-B. Therefore, an electrode pattern having a larger area is formed as compared with a case where drive wiring is individually provided for each VCSEL-B, and a voltage drop is prevented when a drive current flows.

In the single-mode VCSEL having the long resonator structure, since plural longitudinal modes may be present in a reflection band defined by the resonator length, it is required to prevent switching or hopping between the longitudinal modes. Here, an oscillation wavelength band of a required longitudinal mode is set to 940 nm, and the layer 220 causing optical loss for standing waves of an unnecessary longitudinal mode is provided in the resonator extended region 204 so as to prevent switching to an oscillation wavelength band of a longitudinal mode other than the required longitudinal mode. That is, the layer 220 causing optical loss is introduced at a position of a node of standing waves of the required longitudinal mode. The layer 220 causing optical loss is made of a semiconductor material having the same Al composition as a semiconductor layer constituting the resonator extended region 204, and is made of Al_{0.3}Ga_{0.7}As , for example. The layer 220 causing optical loss may have a higher impurity doping concentration than the semiconductor layer constituting the resonator extended region 204. For example, when an impurity concentration of AlGaAs constituting the resonator extended region 204 is 1×10¹⁷ cm⁻³, the layer 220 causing optical loss has an impurity concentration of 1×10¹⁸ cm⁻³, and is configured such that the impurity concentration is higher by about one order of magnitude than that of other semiconductor layers. When the impurity concentration is increased, absorption of light by a carrier is increased, which causes loss. A film thickness of the layer 220 causing optical loss is selected in such a manner that loss to the required longitudinal mode is not increased, and the layer 220 causing optical loss may have a film thickness substantially the same as a film thickness (10 nm to 30 nm) of the current confinement layer 210 located at the node of the standing waves.

The layer 220 causing optical loss is inserted so as to be located at the node relative to the standing waves in the required longitudinal mode. Since the standing waves has low light intensity at the node, an influence of loss caused by the layer 220 causing optical loss on the required longitudinal mode is reduced. On the other hand, for standing waves in an unnecessary longitudinal mode, the layer 220 causing optical loss is located at an antinode other than a node. Since the standing waves at the antinode has higher light intensity than that at the node, loss to the unnecessary longitudinal mode caused by the layer 220 causing optical loss is increased. In this manner, since the loss to the required longitudinal mode is reduced while the loss to the unnecessary longitudinal mode is increased, the unnecessary longitudinal mode is selectively prevented from resonating, and thus hopping between longitudinal modes is prevented.

The layer 220 causing optical loss does not necessarily need to be provided at the position of the node of the standing waves of the required longitudinal mode in the resonator extended region 204, and may be a single layer. In this case, since intensity of standing waves increases as approaching the active region 206, the layer 220 causing optical loss may be formed at a position of a node close to the active region 206. Further, if switching or hopping between longitudinal modes is allowed, the layer 220 causing optical loss may not be provided.

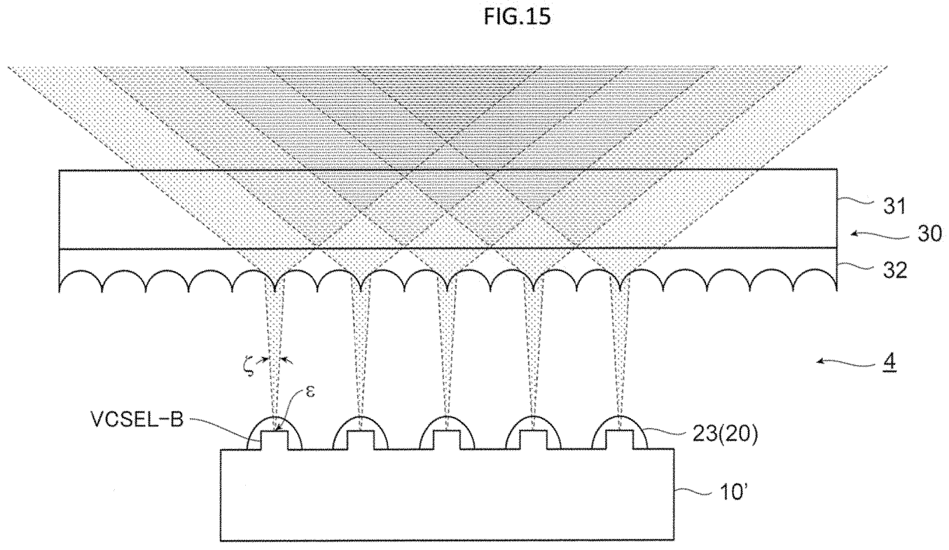

FIG. 15 schematically illustrates a relationship among the light source 10′ in the light-emitting device 4 to which the second exemplary embodiment is applied, the microlenses 23 as an example of the spread angle narrowing member 20, and the diffusion plate 30. In the light-emitting device 4 to which the second exemplary embodiment is applied, the spread angle narrowing member 20 is the microlens 23 provided on the VCSEL-B included in the light source 10′.

The light emitted from the VCSEL-B has the spread angle c smaller than the spread angle a illustrated in FIG. 8 (ε<α). The emitted light is incident on the microlens 23. It is assumed that a size of the cross section perpendicular to the light-emitting direction of the light emitted from the microlens 23 gradually increases or becomes the same as a distance from the VCSEL-A toward the diffusion plate 30 increases. The light emitted from the microlens 23 is light having a spread angle ζ smaller than the spread angle δ illustrated in FIG. 13, and is incident on the diffusion plate 30 (ζ<δ).

Even in a case where the array of microlenses 23 is used as the spread angle narrowing member 20, when the light source 10′ including the VCSEL-B is used, the spread angle ζ is smaller than the spread angle δ in a case where the light source 10 including the VCSEL-A is used, and the light is emitted from the microlens 23. Therefore, the VCSEL-B included in the light source 10′ may be regarded as emitting light at the spread angle ζ smaller than the spread angle ε. Therefore, as illustrated in FIG. 9, the skirt spread amount on the irradiated surface 310 is small. As described above, the light emitted from the microlens 23 may be parallel light.

As described in the first exemplary embodiment and the second exemplary embodiment, the array of the convex lens 21, the fly-eye lens 22, and the microlens 23 has been described as the spread angle narrowing member 20. Since these are optical components, it is easy to control the spread angle of the light emitted from the VCSEL which is a light-emitting element.

Here, as the spread angle of the light incident on the diffusion plate 30 is smaller, the skirt spread amount on the irradiated surface 310 is smaller, and thus, in the measurement of the three-dimensional shape by the TOF method in which the light sources 10 and 10′ having large light output are required, the spread angle of the light emitted from the VCSELs included in the light sources 10 and 10′ is narrowed by using the spread angle narrowing member 20, and the light is incident on the diffusion plate 30. Accordingly, the Skirt spread amount, that is, wasteful light spreading by drawing the skirt outside the predetermined range (detection range I) on the irradiated surface 310 is reduced, and the light use efficiency is improved. In this way, power consumption of the light source is reduced as compared with a case where the skirt spread amount is not reduced. In particular, a long driving time is achieved in an information processing device driven by a battery, such as a portable information processing device.

In the first exemplary embodiment and the second exemplary embodiment described above, an example in which the plural VCSELs (VCSEL-As and VCSEL-Bs) are connected in parallel has been described, but a configuration in which the plural VCSELs are connected in series or a connection configuration in which series connection and parallel connection are combined may be used.

Further, in the first exemplary embodiment and the second exemplary embodiment described above, an example in which the plural VCSELs (VCSEL-As and VCSEL-Bs) are configured in a mesa shape has been described, but the VCSELs may be configured in a form other than a mesa shape. For example, plural holes may be provided to surround the emission port of each VCSEL, and the current confinement layer (the current confinement layers 110 and 210) may be oxidized using the holes so as to form a VCSEL having an oxidized confinement structure.

Further, in the first exemplary embodiment and the second exemplary embodiment described above, the plural VCSELs (VCSEL-As and VCSEL-Bs) emit light from the surface side (front surface side) on which the epitaxial layer is formed on the board 100, but light may be emitted from a surface side (back surface side) on which the epitaxial layer is not formed.

In the first exemplary embodiment and the second exemplary embodiment described above, the light sources 10 and 10′ and the diffusion plate 30 are disposed at positions overlapping each other when viewed from the light emission surface side, but the light sources 10 and 10′ and the diffusion plate 30 may be disposed at positions not overlapping each other. For example, a configuration in which light may be diffused via a reflection member such as a reflection mirror even though the diffusion plate 30 and the light sources 10 and 10′ are disposed at positions not overlapping each other may be adopted.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light-emitting device comprising:
a light source comprising a plurality of light-emitting elements;
a first optical member that is provided in a light-emitting path of the light source, the first optical member being configured to narrow a spread angle of light emitted from each of the light-emitting elements of the light source and emit the narrowed light; and
a second optical member that is provided on a light-emitting side of the first optical member and is configured to diffuse and irradiate light incident from the first optical member.

2. The light-emitting device according to claim 1,
wherein the first optical member is an optical component that narrows a spread angle of light by refraction.

3. The light-emitting device according to claim 1,
wherein the first optical member is provided on the light-emitting elements of the light source.

4. The light-emitting device according to claim 2,
wherein the first optical member is provided on the light-emitting elements of the light source.

5. The light-emitting device according to claim 1,
wherein the first optical member is a microlens provided for each of the light-emitting elements of the light source.

6. The light-emitting device according to claim 2,
wherein the first optical member is a microlens provided for each of the light-emitting elements of the light source.

7. The light-emitting device according to claim 3,
wherein the first optical member is a microlens provided for each of the light-emitting elements of the light source.

8. The light-emitting device according to claim 4,
wherein the first optical member is a microlens provided for each of the light-emitting elements of the light source.

9. The light-emitting device according to claim 1,
wherein the first optical member is configured to convert light incident from each of the light-emitting elements of the light source into parallel light and emit the parallel light.

10. The light-emitting device according to claim 1,
wherein the light-emitting element is a vertical cavity surface emitting laser.

11. The light-emitting device according to claim 10,
wherein the vertical cavity surface emitting laser has a long resonator structure.

12. The light-emitting device according to claim 1,
wherein the plurality of light-emitting elements are connected in parallel to each other by an electrode pattern, and the electrode pattern covers a region excluding an emission port of each of the light-emitting elements in a continuous pattern.

13. The light-emitting device according to claim 1,
wherein the second optical member is configured to change directivity of the light emitted from the first optical member and emit the light.

14. The light-emitting device according to claim 13,
wherein the second optical member is a plate-like member having a structure for changing the directivity of the light on at least one surface of the plate-like member.

15. The light-emitting device according to claim 1,
wherein the second optical member is a plate-like member having a plurality of concave portions and convex portions on at least one surface of the plate-like member.

16. The light-emitting device according to claim 1,
wherein the second optical member is configured to emit light used for measuring a three-dimensional shape by a time-of-flight method.

17. The light-emitting device according to claim 1,
wherein the light source, the first optical member, and the second optical member are mounted on a portable information processing terminal, and the light source is driven by a battery of the portable information processing terminal.

18. An optical device comprising:
the light-emitting device according to claim 1; and
a light-receiving unit configured to
receive light that is emitted from a light source of the light-emitting device and reflected by a measurement target, and
output a signal corresponding to a time from when the light is emitted from the light source to when the light is received by the light-receiving unit.

19. An information processing device comprising:
the optical device according to claim 18; and
a shape identifying unit configured to identify a three-dimensional shape of a measurement target based on light that is emitted from a light source of the optical device, reflected by the measurement target, and received by a light-receiving unit of the optical device.

20. The information processing device according to claim 19, further comprising an authentication processing unit configured to perform an authentication process related to use of the information processing device based on a result of identification performed by the shape identifying unit.
